(19) United States
(12) Patent Application Publication
(10) Pub. No.: US 2016/0013763 A1
(43) Pub. Date: Jan. 14, 2016

(54) AMPLIFIER CIRCUIT, CMOS INVERTER AMPLIFIER CIRCUIT, COMPARATOR CIRCUIT, DELTA-SIGMA ANALOG-TO-DIGITAL CONVERTER, AND SEMICONDUCTOR DEVICE

(71) Applicant: Semiconductor Technology Academic Research Center, Yokohama-shi (JP)

(72) Inventors: Kazuki TOMIMATSU, Yokohama-shi (JP); Hiroyuki ITO, Yokohama-shi (JP); Noboru ISHIHARA, Yokohama-shi (JP); Kazuya MASU, Yokohama-shi (JP)

(21) Appl. No.: 14/732,008

(22) Filed: Jun. 5, 2015

(30) Foreign Application Priority Data
Jul. 10, 2014 (JP) 2014-142517

(51) Int. Cl. H03F 1/30; H03K 5/125; H03M 3/00; H03F 3/45

(52) U.S. Cl. CPC H03F 1/301; H03F 3/45179; H03K 5/125; H03M 3/458; H03F 2203/45116

(57) ABSTRACT

An amplifier circuit includes a first MOS transistor whose source is connected to a first power source and which amplifies a signal that is input to a gate and outputs the amplified signal from a drain, a second MOS transistor whose source is connected to the first power source, and a back gate voltage control element that controls the voltage a back gate of the second MOS transistor so that the voltage associated with the drain of the second MOS transistor and the voltage of the gate of the second MOS transistor are equal to each other, and which applies the controlled voltage to the back gate of the first MOS transistor.

### CROSS-REFERENCE TO RELATED APPLICATION

This application is based on upon and claims the benefit of priority of the prior Japanese Patent Application No. 2014-142517, filed on Jul. 10, 2014, the entire contents of which are incorporated herein by reference.

### FIELD

The present invention relates to an amplifier circuit, a CMOS inverter amplifier circuit, a comparator circuit, a ΔΣ analog-to-digital converter, and a semiconductor device.

### BACKGROUND

A circuit formed by a MOS transistor, such as a CMOS inverter circuit, is capable of low-voltage operation, and therefore is used as a logic element of a low power source voltage digital circuit. Further, the circuit formed by a MOS transistor has characteristics of being capable of operating on a low voltage, and therefore is expected to be used as a low-voltage/low-power basic amplifier circuit. However, the MOS transistor is subject to the influence of fluctuations in the power source voltage, the operating temperature, and the manufacturing condition, and therefore a conventional basic amplifier circuit formed by a MOS transistor fluctuates in gain due to the fluctuations in the power source voltage, the operating temperature, and the manufacturing condition.

FIG. 1 is a circuit block diagram of a CMOS inverter amplifier circuit described in Non-Patent Document 1.

A CMOS inverter amplifier circuit 900 has a first inverter 901, a second inverter 902 to which an output signal of the first inverter 901 is input, and a third inverter 903 to which an output signal of the second inverter 902 is input. Each of the first inverter 901, the second inverter 902, and the third inverter 903 is a CMOS inverter having an nMOS transistor and a pMOS transistor. The first inverter 901 is connected in series between a power source voltage Vdd and the ground and to which an input voltage of ½·Vdd divided by a first resistor 111 and a second resistor 112 having an identical resistance value R is input.

The CMOS inverter amplifier circuit 900 optimizes a delay in an element that is arranged in a critical path by controlling the threshold voltage by using ABB (Active Body Bias). In other words, the CMOS inverter amplifier circuit 900 controls the threshold voltage of the nMOS transistor by feeding back the output voltage to the back gate of the nMOS transistor of the first inverter 901 to the third inverter 903. In the CMOS inverter amplifier circuit 900, the threshold voltage is controlled so as to become ½·Vdd regardless of the fluctuations in the power source voltage, the operating temperature, and the manufacturing condition. If the threshold voltage of the first inverter 901 becomes lower than ½·Vdd and the input voltages of the second inverter 902 and the third inverter 903 drop, the voltage of the back gate of the nMOS transistor drops and the threshold voltage of each inverter increases. On the other hand, if the threshold voltage of the first inverter 901 becomes higher than ½·Vdd and the input voltages of the second inverter 902 and the third inverter 903 increase, the voltage of the back gate of the nMOS transistor increases and the threshold voltage of each inverter drops. In the CMOS inverter amplifier circuit 900, the threshold voltage of the nMOS transistor is controlled by a negative feedback circuit and thus the threshold voltage is kept at ½·Vdd. The output signal of the CMOS inverter amplifier circuit 900 is output to the back gate of a MOS transistor, not illustrated, which is arranged in the critical path.

### RELATED DOCUMENTS

[Non-Patent Document 1] “0.5-V analog circuit techniques and their application in OTA and filter design”, S. Chatterjee, Y. Tsivids, Y. and P. Kinget, IEEE J. Solid-State Circuits, Vol. 40, no. 12, pp. 2373-2387, December 2005

### SUMMARY

However, in the CMOS inverter amplifier circuit 900 described in Non-Patent Document 1, only the back gate voltage of the nMOS transistor is controlled, and therefore there is such a problem that it is not possible to reflect fluctuations in the threshold voltage of the pMOS transistor in the control. Further, the CMOS inverter amplifier circuit 900 has such a problem that the circuit operation becomes unstable when the gain condition and the phase condition between the input signal and the output signal become predetermined conditions, and in a worst case, an oscillation state may be brought about. Furthermore, the CMOS inverter amplifier circuit 900 has such a problem the CMOS inverter amplifier circuit 900 controls the fluctuations in the manufacturing condition only in a narrow range. As described above, with the CMOS inverter amplifier circuit 900 described in Non-Patent Document 1, it is not easy to provide an amplifier circuit having desired direct-current transfer characteristics.

Thus, an object of the present invention is to provide an amplifier circuit having desired direct-current transfer characteristics by controlling the threshold value of the MOS transistor that forms an amplifier unit.

An amplifier circuit according to the present invention includes a first MOS transistor whose source is connected to a first power source and which amplifies a signal that is input to a gate and outputs the amplified signal from a drain a second MOS transistor whose source is connected to the first power source and a back gate voltage control element that controls the voltage a back gate of the second MOS transistor so that the voltage associated with the drain of the second MOS transistor and the voltage of the gate of the second MOS transistor are equal to each other, and which applies the controlled voltage to the back gate of the first MOS transistor.

Further, in the amplifier circuit according to the present invention, it is preferable for the back gate voltage control element to be an operational amplifier.

Further, in the operational amplifier of the amplifier circuit according to the present invention, it is preferable for the number of stages of MOS transistors that are connected in series between the first power source and a second power source whose voltage is different from that of the first power source to be two or less.

Further, it is preferable for the amplifier circuit according to the present invention to further include a gate voltage adjustment circuit configured to adjust the gate voltage of the second MOS transistor.

Further, it is preferable for the amplifier circuit according to the present invention to further include a gate-drain voltage adjustment circuit configured to adjust the voltage between the gate and the drain of the second MOS transistor.

A CMOS inverter amplifier circuit according to the present invention includes a CMOS inverter having a first nMOS transistor whose gate is connected to an input terminal, whose source is connected to a first power source, and whose drain is connected to an output terminal, and a first pMOS transistor whose gate is connected to the input terminal, whose source is connected to a second power source whose voltage is different from the voltage of the first power source, and whose drain is connected to the output terminal, and amplifying a signal that is input to the input terminal and outputting the amplified signal from the output terminal, a second nMOS transistor whose source is connected to the first power source, a second pMOS transistor whose source is connected to the second power source, an nMOS back gate voltage control element that controls the voltage of the back gate of the second nMOS transistor so that the voltage associated with the drain of the second nMOS transistor and the voltage of the gate of the second nMOS transistor are equal to each other, and which applies the controlled voltage to the back gate of the first nMOS transistor, and a pMOS back gate voltage control element that controls the voltage of the back gate of the second pMOS transistor so that the voltage associated with the drain of the second pMOS transistor and the voltage of the gate of the second pMOS transistor are equal to each other, and which applies the controlled voltage to the back gate of the first pMOS transistor.

A comparator circuit according to the present invention includes a first MOS transistor whose source is connected to a first power source and which amplifies a signal that is input to a gate and outputs the amplified signal from a drain, a second MOS transistor whose source is connected to the first power source, and a back gate voltage control element that controls the voltage a back gate of the second MOS transistor so that the voltage associated with the drain of the second MOS transistor and the voltage of the gate of the second MOS transistor are equal to each other, and which applies the controlled voltage to the back gate of the first MOS transistor.

A comparator circuit according to the present invention includes a CMOS inverter having a first nMOS transistor whose gate is connected to an input terminal, whose source is connected to a first power source, and whose drain is connected to an output terminal, and a first pMOS transistor whose gate is connected to the input terminal, whose source is connected to a second power source whose voltage is different from the voltage of the first power source, and whose drain is connected to the output terminal, and amplifying a signal that is input to the input terminal and outputting the amplified signal from the output terminal, a second nMOS transistor whose source is connected to the first power source, a second pMOS transistor whose source is connected to the second power source, an nMOS back gate voltage control element that controls the voltage of the back gate of the second nMOS transistor so that the voltage associated with the drain of the second nMOS transistor and the voltage of the gate of the second nMOS transistor are equal to each other, and which applies the controlled voltage to the back gate of the first nMOS transistor, and a pMOS back gate voltage control element that controls the voltage of the back gate of the second pMOS transistor so that the voltage associated with the drain of the second pMOS transistor and the voltage of the gate of the second pMOS transistor are equal to each other, and which applies the controlled voltage to the back gate of the first pMOS transistor.

A ΔΣ analog-to-digital converter according to the present invention includes an adder configured to add an analog signal and a feedback signal, an integral circuit including the CMOS inverter amplifier circuit, a quantizer configured to quantize an output signal of the integral circuit, and a feedback circuit configured to delay an output signal of the quantizer, to carry out digital-to-analog converter, and to output the feedback signal, wherein CMOS inverter amplifier circuit including a CMOS inverter having a first nMOS transistor whose gate is connected to an input terminal, whose source is connected to a first power source, and whose drain is connected to an output terminal, and a first pMOS transistor whose gate is connected to the input terminal, whose source is connected to a second power source whose voltage is different from the voltage of the first power source, and whose drain is connected to the output terminal, and amplifying a signal that is input to the input terminal and outputting the amplified signal from the output terminal, a second nMOS transistor whose source is connected to the first power source, a second pMOS transistor whose source is connected to the second power source, an nMOS back gate voltage control element that controls the voltage of the back gate of the second nMOS transistor so that the voltage associated with the drain of the second nMOS transistor and the voltage of the gate of the second nMOS transistor are equal to each other, and which applies the controlled voltage to the back gate of the first nMOS transistor, and a pMOS back gate voltage control element that controls the voltage of the back gate of the second pMOS transistor so that the voltage associated with the drain of the second pMOS transistor and the voltage of the gate of the second pMOS transistor are equal to each other, and which applies the controlled voltage to the back gate of the first pMOS transistor.

Further, in the ΔΣ analog-to-digital converter according to the present invention, it is preferable for the quantizer to include the comparator circuit including a CMOS inverter having a first nMOS transistor whose gate is connected to an input terminal, whose source is connected to a first power source, and whose drain is connected to an output terminal, and a first pMOS transistor whose gate is connected to the input terminal, whose source is connected to a second power source whose voltage is different from the voltage of the first power source, and whose drain is connected to the output terminal, and amplifying a signal that is input to the input terminal and outputting the amplified signal from the output terminal, a second nMOS transistor whose source is connected to the first power source, a second pMOS transistor whose source is connected to the second power source, an nMOS back gate voltage control element that controls the voltage of the back gate of the second nMOS transistor so that the voltage associated with the drain of the second nMOS transistor and the voltage of the gate of the second nMOS transistor are equal to each other, and which applies the controlled voltage to the back gate of the first nMOS transistor, and a pMOS back gate voltage control element that controls the voltage of the back gate of the second pMOS transistor so that the voltage associated with the drain of the second pMOS transistor and the voltage of the gate of the second pMOS transistor are equal to each other, and which applies the controlled voltage to the back gate of the first pMOS transistor.

A semiconductor device according to the present invention includes a MOS transistor whose source is connected to a first power source, and a variation detection circuit having a back gate voltage detection element that controls the voltage of a back gate of the MOS transistor so that the voltage associated with the MOS transistor and the voltage of the gate of the MOS transistor are equal to each other, and which outputs an output signal indicating the controlled voltage.

It is possible for the amplifier circuit according to the present invention to have desired direct-current transfer characteristics by controlling the threshold value of the MOS transistor that forms an amplifier unit.

### BRIEF DESCRIPTION OF THE DRAWINGS

FIG. 1 is a circuit block diagram of a conventional CMOS inverter amplifier circuit;

FIG. 2 is a circuit block diagram of an amplifier circuit according to a first embodiment;

FIG. 3 is an internal circuit diagram of the back gate voltage control element illustrated in FIG. 2;

FIG. 4 is a diagram illustrating an example of the direct-current transfer characteristics of the first nMOS transistor illustrated in FIG. 2;

FIG. 5 is a circuit block diagram of an amplifier circuit according to a second embodiment;

FIG. 6 is circuit block diagram of an amplifier circuit according to a third embodiment;

FIG. 7A is a diagram illustrating fluctuations in direct-current transfer characteristics due to the variation in manufacturing of a conventional CMOS inverter amplifier circuit;

FIG. 7B is a diagram illustrating fluctuations in direct-current transfer characteristics due to the variation in manufacturing of the amplifier circuit illustrated in FIG. 6;

FIG. 8A is a diagram illustrating fluctuations in frequency transfer characteristics of gain due to the variation in manufacturing of the conventional CMOS inverter amplifier circuit;

FIG. 8B is a diagram illustrating fluctuations in frequency transfer characteristics of gain due to the variation in manufacturing of the amplifier circuit illustrated in FIG. 6;

FIG. 9A is a diagram illustrating the fluctuations in the gain due to the fluctuations in the power source voltage of the conventional CMOS inverter amplifier circuit and the amplifier circuit illustrated in FIG. 6;

FIG. 9B is a diagram illustrating the fluctuations in the frequency in the case of the unity gain due to the fluctuations in the power source voltage of the conventional CMOS inverter amplifier circuit and the amplifier circuit illustrated in FIG. 6;

FIG. 9C is a diagram illustrating the fluctuations in the gain due to fluctuations in operating temperature of the conventional CMOS inverter amplifier circuit and the amplifier circuit illustrated in FIG. 6;

FIG. 9D is a diagram illustrating the fluctuations in the frequency in the case of the unity gain due to the fluctuations in operating temperature of the conventional CMOS inverter amplifier circuit and the amplifier circuit illustrated in FIG. 6;

FIG. 10 is a circuit block diagram of an amplifier circuit according to a fourth embodiment;

FIG. 11 is a circuit block diagram of an amplifier circuit according to a fifth embodiment;

FIG. 12 is a circuit block diagram of an amplifier circuit according to a sixth embodiment;

FIG. 13 is a circuit block diagram of an amplifier circuit according to a seventh embodiment;

FIG. 14 is a circuit block diagram of an amplifier circuit according to an eighth embodiment;

FIG. 15A is a diagram illustrating the direct-current transfer characteristics of the first nMOS transistor when the step-down voltage ΔV of the level shift element is changed in the amplifier circuit illustrated in FIG. 14;

FIG. 15B is a diagram illustrating the direct-current transfer characteristics of the first nMOS transistor when the control voltage Vg of the gate voltage adjustment circuit is changed in the amplifier circuit illustrated in FIG. 14;

FIG. 16 is a circuit block diagram of an amplifier circuit according to a ninth embodiment;

FIG. 17 is a circuit block diagram of an amplifier circuit according to a tenth embodiment;

FIG. 18A is a plan view of a semiconductor wafer according to an embodiment;

FIG. 18B is a plan view of a semiconductor device that is formed on the semiconductor wafer illustrated in FIG. 18A;

FIG. 18C is a circuit diagram of a variation detection circuit that is mounted on the semiconductor device illustrated in FIG. 18B;

FIG. 18D is a circuit diagram of a variation detection circuit that is mounted on the semiconductor device illustrated in FIG. 18B;

FIG. 19 is a circuit block diagram of a ΔΣ analog-to-digital converter circuit according to an embodiment;

FIG. 20 is a diagram illustrating fluctuations in SNDR of the conventional ΔΣAD converter circuit and the ΔΣAD converter circuit illustrated in FIG. 19 due to the variation in manufacturing;

FIG. 21A is a diagram illustrating the fluctuations in the SNDR due to the fluctuations in the power source voltage of the conventional ΔΣAD converter circuit and the ΔΣAD converter circuit illustrated in FIG. 19;

FIG. 21B is a diagram illustrating the fluctuations in the SNDR due to the fluctuations in the operating temperature of the conventional ΔΣAD converter circuit and the ΔΣAD converter circuit illustrated in FIG. 19; and

FIG. 22 is a circuit block diagram of a ΔΣ analog-to-digital converter circuit according to another embodiment.

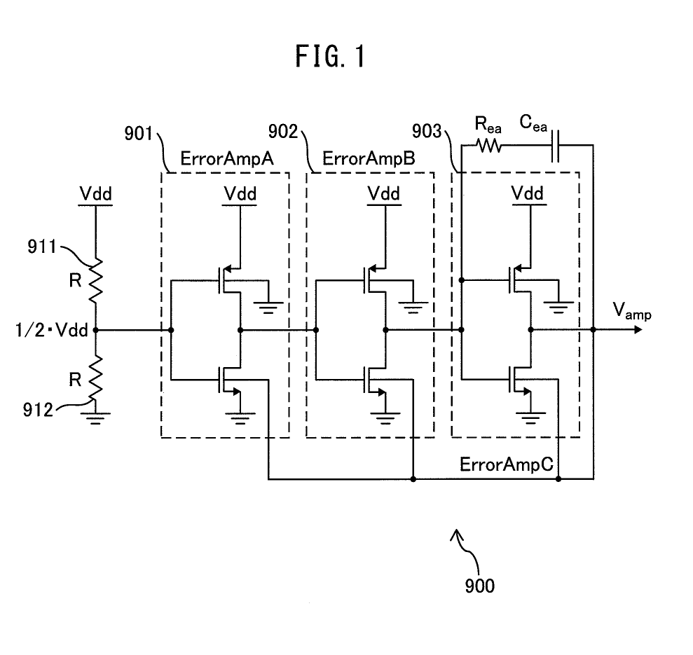

### DESCRIPTION OF EMBODIMENTS

Hereinafter, with reference to the drawings, an amplifier circuit, a CMOS inverter amplifier circuit, a comparator circuit, a ΔΣ analog-to-digital converter, and a semiconductor device according to the present invention are explained. However, it should be noted that the technical scope of the present invention is not limited to those embodiments but encompasses equivalents to the inventions described in the claims. Hereinafter, components to which the same reference symbols are attached in different drawings refer to those having the same functions.

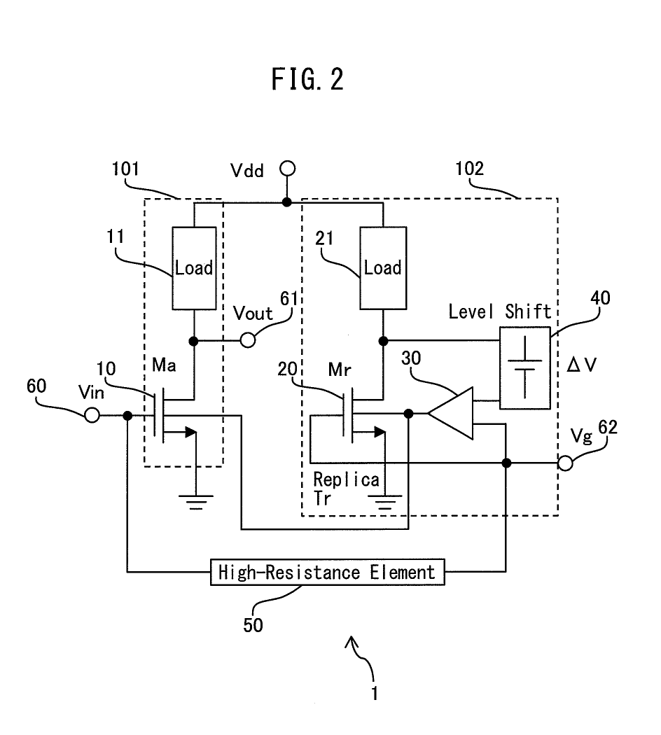

FIG. 2 is a circuit block diagram of an amplifier circuit according to a first embodiment.

An amplifier circuit 1 has a first nMOS transistor 10, a first nMOS load 11, a second nMOS transistor 20, a second nMOS load 21, a back gate voltage control element 30, a level shift element 40, and a high-resistance element 50. The amplifier circuit 1 further has a signal input terminal 60, a signal output terminal 61, and a gate input terminal 62. An input signal Vin having a predetermined direct-current component and a predetermined amplitude is input to the signal input terminal 60. An output voltage Vout obtained by amplifying the amplitude of the input signal Vin is output from the signal output terminal 61. A gate voltage that is input to the gate of the second nMOS transistor 20 and to the first input terminal of the back gate voltage control element 30 in order to determine the threshold voltage and direct-current transfer characteristics of the first nMOS transistor 10 is input to the gate input terminal 62.

The gate of the first nMOS transistor 10 is connected to the signal input terminal 60, the source is grounded, the drain is connected to the signal output terminal 61, and the back gate is connected to the output terminal of the back gate voltage control element 30. The first nMOS load 11 is a resistance element and one end thereof is connected to a power source voltage Vdd and the other end is connected to the signal output terminal 61 as well as to the drain of the first nMOS transistor 10. The first nMOS transistor 10 and the first nMOS load 11 form an amplifier unit 101 configured to amplify a signal that is input to the signal input terminal 60 and to output the amplified signal from the signal output terminal 61.

The gate of the second nMOS transistor 20 is connected to the gate input terminal 62, the source is grounded, the drain is connected to the level shift element 40 as well as to the second nMOS load 21, and the back gate is connected to the output terminal of the back gate voltage control element 30. The second nMOS load 21 is a resistance element and one end thereof is connected to the power source voltage Vdd and the other end is connected to the level shift element 40 as well as to the drain of the second nMOS transistor 20.

The second nMOS transistor 20 has the same structure as that of the first nMOS transistor 10 and functions as a replica transistor for controlling the threshold voltage of the first nMOS transistor 10.

The back gate voltage control element 30 is an operational amplifier and the first input terminal thereof is connected to the gate input terminal 62 as well as to the gate of the second nMOS transistor 20 and the second input terminal is connected to the level shift element 40. The output terminal of the back gate voltage control element 30 is connected to the back gates of the first nMOS transistor 10 and the second nMOS transistor 20.

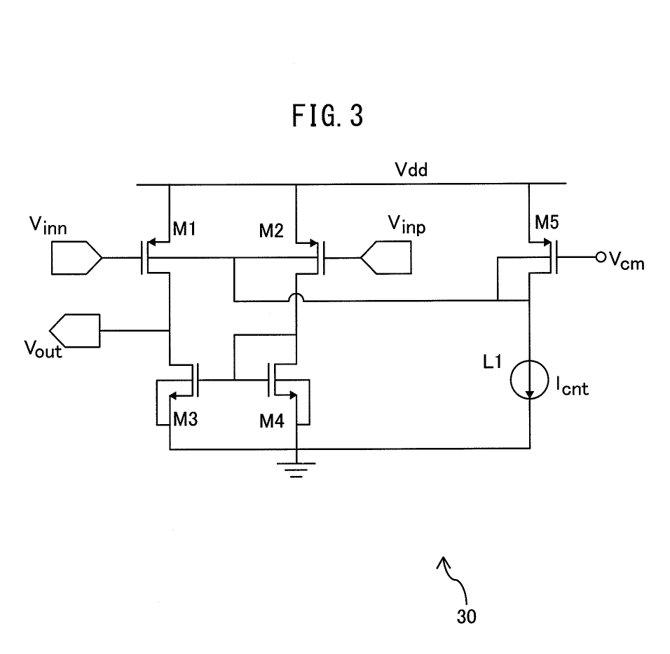

FIG. 3 is an internal circuit diagram of the back gate voltage control element 30.

The back gate voltage control element 30 has a first MOS transistor M1, a second MOS transistor M2, a third MOS transistor M3, a fourth MOS transistor M4, a fifth MOS transistor M5, and a constant current load L1.

The first MOS transistor M1, the second MOS transistor M2, and the fifth MOS transistor M5 are pMOS transistors and each source is connected to the power source voltage Vdd. The third MOS transistor M3 and the fourth MOS transistor M4 are nMOS transistors and each source is grounded. One of the input signals of the back gate voltage control element 30 is input to the gate of the first MOS transistor M1 and the other input signal of the back gate voltage control element 30 is input to the gate of the second MOS transistor M2. The drain of the first MOS transistor M1 is connected to the drain of the third MOS transistor M3 and the drain of the second MOS transistor M2 is connected to the drain of the fourth MOS transistor M4. The gate of the third MOS transistor M3 and the gate and drain of the fourth MOS transistor M4 are connected to each other. The third MOS transistor M3 and the fourth MOS transistor M4 form a current mirror circuit and function as the load of the first MOS transistor M1 and the second MOS transistor M2.

A reference voltage Vcm is applied to the gate of the fifth MOS transistor M5 and the drain of the fifth MOS transistor M5 is connected to the back gates of the first MOS transistor M1, the second MOS transistor M2, and the fifth MOS transistor M5, and to the constant current load L1. In one example, the reference voltage Vcm is ½·Vdd. The constant current load L1 is a resistance element and a load that causes a reference current Icnt to flow, which is in accordance with the reference voltage applied to the gate of the fifth MOS transistor M5. The fifth MOS transistor M5 and the constant current load L1 function as a reference current circuit. The back gate of the fifth MOS transistor M5 is connected to the back gates of the first MOS transistor M1 and the second MOS transistor M2. Thus, the threshold value of the first MOS transistor M1, that of the second MOS transistor M2, and that of the fifth MOS transistor M5 are equal to one another. The threshold voltages of the first MOS transistor M1, the second MOS transistor M2, and the fifth MOS transistor M5 are equal to one another, and therefore the first MOS transistor M1 and the second MOS transistor M2 are controlled so that a current in accordance with the reference current Icnt flows.

In the back gate voltage control element 30, the number of MOS transistors that are connected in series between the power source voltage Vdd and the ground is two or less. Between the power source Vdd and the ground, the first MOS transistor M1 and the third MOS transistor M3 are connected in series and at the same time, the second MOS transistor M2 and the fourth MOS transistor M4 are connected in series. The fifth MOS transistor M5 is connected in series with the constant current load L1, which is a resistance element, between the power source voltage Vdd and the ground. The back gate voltage control element 30 is capable of a low-voltage operation, since the number of MOS transistors that are connected in series between the power source voltage Vdd and the ground is two or less.

The level shift element 40 includes a circuit having a plurality of diodes connected in series and inputs a voltage obtained by stepping down the drain voltage of the second nMOS transistor 20 to the first input terminal of the back gate voltage control element 30. The step-down voltage stepped down by the level shift element 40 is indicated by ΔV.

The second nMOS transistor 20, the second nMOS load 21, the back gate voltage control element 30, and the level shift element 40 form a back gate voltage control circuit 102 configured to control the voltage that is applied to the back gate of the first nMOS transistor 10. A gate voltage Vg that is input to the gate input terminal 62 are applied to both the first input terminal of the back gate voltage control element 30 and the gate of the second nMOS transistor 20. A voltage (Vd−ΔV) that is obtained by stepping down the drain voltage of the second nMOS transistor 20 by ΔV is applied to the second input terminal of the back gate voltage control element 30. Further, the back gate voltage control element 30 applies a voltage to the back gate of the second nMOS transistor 20, which will cause the voltage Vg that is applied to the first input terminal and the voltage (Vd−ΔV) that is applied to the second input terminal become equal to each other, satisfying the relationship of (Vg=Vd−ΔV). Thus, the back gate voltage control element 30 applies a voltage that will cause the drain voltage Vd when the gate voltage Vg is applied to the gate via the gate input terminal 62 to become (Vg+ΔV) to the back gate of the second nMOS transistor 20.

Further, the back gate voltage control element 30 applies a voltage equal to the voltage that is applied to the back gate of the second nMOS transistor 20 to the back gate of the first nMOS transistor 10. Since the first nMOS transistor 10 and the second nMOS transistor 20 have the same structure, when the voltages that are applied to the back gates of both the transistors are equal, the threshold voltages of both the transistors are equal. When the threshold voltage of the first nMOS transistor 10 and that of the second nMOS transistor 20 become equal to each other, the direct-current transfer characteristics of the first nMOS transistor 10 and those of the second nMOS transistor 20 become equal to each other.

The threshold voltage of the first nMOS transistor 10 is controlled so as to become a desired value by the back gate voltage control element 30 using the second nMOS transistor 20 that functions as a replica transistor. In other words, in the amplifier circuit 1, the back gate voltage control circuit 102 controls the threshold voltage of the first nMOS transistor 10 so as to have the direct-current transfer characteristics such that the drain voltage Vd becomes (Vd=Vg+ΔV) when the gate voltage is Vg.

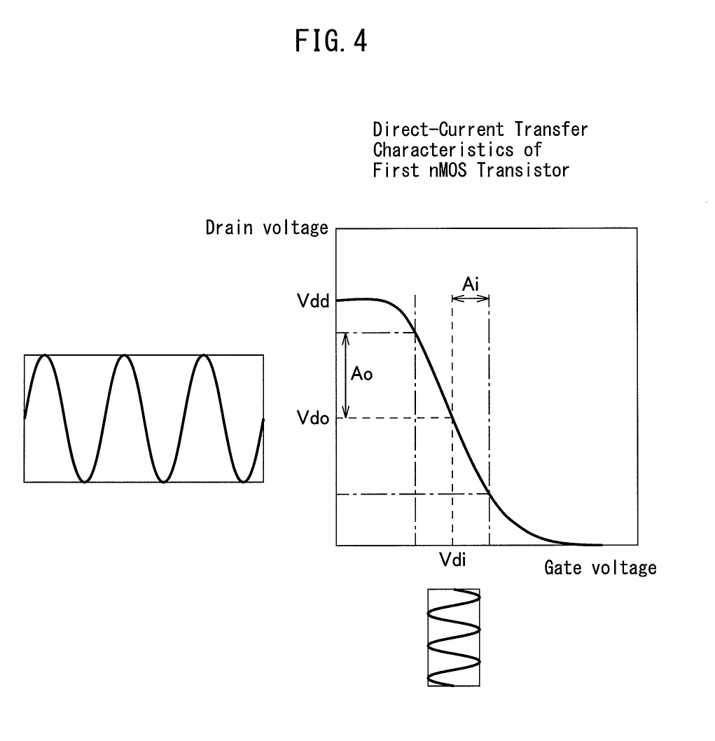

FIG. 4 is a diagram illustrating an example of the direct-current transfer characteristics of the first nMOS transistor 10. In FIG. 4, the horizontal axis represents the gate voltage of the first nMOS transistor 10 and the vertical axis represents the drain voltage of the first nMOS transistor 10. Further, in FIG. 4, a waveform illustrated below the vertical axis indicates an example of the input voltage Vin that is input to the input terminal and a waveform illustrated adjacent to the horizontal axis indicates an example of the output voltage Vout that is output from the output terminal.

When a signal whose direct-current component is Vdi and having an amplitude of Ai is input to the gate of the first nMOS transistor 10 as the input signal Vin, a signal whose direct-current component is Vdo and having an amplitude of Ao is output from the drain of the first nMOS transistor 10. When the gate voltage Vg that is applied to the gate input terminal 62 is applied as the direct-current component Vdi of the input signal Vin, the direct-current component Vdi of the input signal Vin and the direct-current component Vdo of the output signal Vout have a relationship of (Vdo=Vdi+ΔV). The amplifier factor between the amplitude Ai of the input signal Vin and the amplitude Ao of the output voltage Vout is determined in accordance with the slope of the direct-current transfer characteristics of the first MOS transistor 10.

The high-resistance element 50 is a resistance element having a very high resistance value and one end thereof is connected to the signal input terminal 60 and the other end is connected to the gate input terminal 62. The high-resistance element 50 functions so as to prevent the alternating-current signal component of the input signal Vin from propagating to the back gate voltage control circuit 102 and to enable the voltage Vg that is applied to the gate input terminal as the direct-current component Vdi to be supplied stably. The high-resistance element 50 may be omitted.

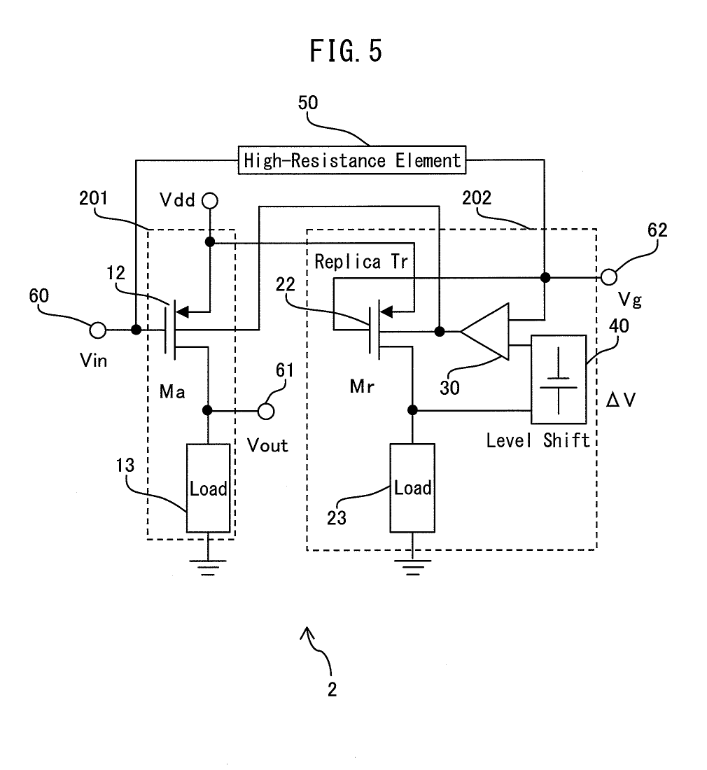

FIG. 5 is a circuit block diagram of an amplifier circuit according to a second embodiment.

An amplifier circuit 2 has a first pMOS transistor 12, a first pMOS load 13, a second pMOS transistor 22, a second pMOS load 23, the back gate voltage control element 30, the level shift element 40, and the high-resistance element 50. Further, the amplifier circuit 2 has the signal input terminal 60, the signal output terminal 61, and the gate input terminal 62.

The amplifier circuit 2 differs from the amplifier circuit 1 according to the first embodiment in that the MOS transistor forming the amplifier unit is not the nMOS transistor but the pMOS transistor. Since the MOS transistor forming the amplifier unit is formed by the pMOS transistor, the second pMOS transistor 22 that is a pMOS transistor and which has the same structure as that of the first pMOS transistor 12 is arranged as a replica transistor. The first pMOS load 13 and the second pMOS load 23 are the resistance elements like the first nMOS load 11.

The first pMOS transistor 12 and the first pMOS load 13 form an amplifier unit 201 configured to amplify a signal that is input to the signal input terminal 60 and to output the amplified signal from the signal output terminal 61. The second pMOS transistor 22, the second pMOS load 23, the back gate voltage control element 30, and the level shift element 40 form a back gate voltage control circuit 202 configured to control the voltage that is applied to the back gate of the first pMOS transistor 12. In the amplifier circuit 2, the back gate voltage control circuit 202 controls the threshold voltage of the first pMOS transistor 12 so as to have the direct-current transfer characteristics such that the drain voltage Vd becomes (Vg−ΔV) when the gate voltage is Vg.

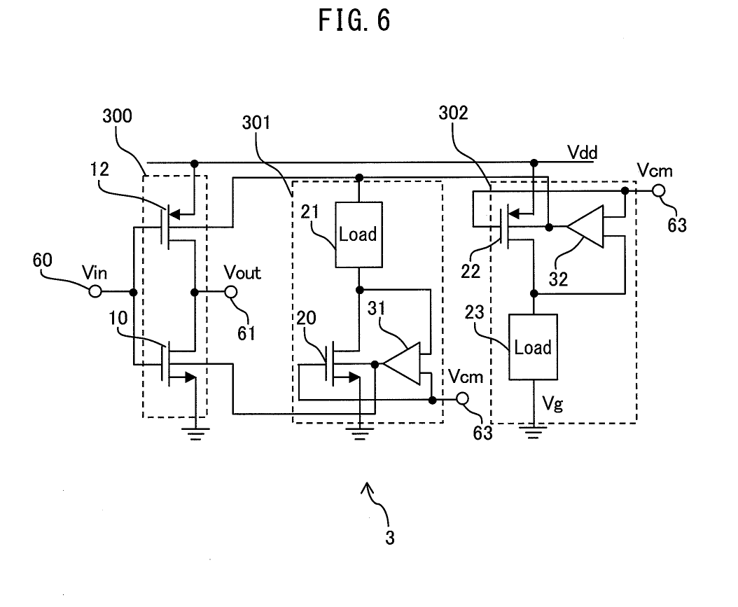

FIG. 6 is circuit block diagram of an amplifier circuit according to a third embodiment.

An amplifier circuit 3 has the first nMOS transistor 10, the first pMOS transistor 12, the second nMOS transistor 20, the second nMOS load 21, the second pMOS transistor 22, and the second pMOS load 23. Further, the amplifier circuit 3 has a first back gate voltage control element 31, a second back gate voltage control element 32, the signal input terminal 60, the signal output terminal 61, and a reference signal input terminal 63.

The gates of the first nMOS transistor 10 and the first pMOS transistor 12 are connected to the signal input terminal 60 and the drains thereof are connected to the signal output terminal 61. The source of the first nMOS transistor 10 is grounded and the source of the first pMOS transistor 12 is connected to the power source voltage Vdd. The first nMOS transistor 10 and the first pMOS transistor 12 form a CMOS inverter amplifier unit 300 configured to amplify a signal that is input to the signal input terminal 60 and to output the amplified signal from the signal output terminal 61.

The gate of the second nMOS transistor 20 is connected to the reference signal input terminal 63 as well as to the first input terminal of the first back gate voltage control element 31, the source is grounded, and the drain is connected to the second input terminal of the first back gate voltage control element 31 as well as to the second nMOS load 21. Further, the back gate of the second nMOS transistor 20 is connected to the output terminal of the first back gate voltage control element 31. The first back gate voltage control element 31 has the same configuration and function as those of the back gate voltage control element 30. The second nMOS transistor 20, the second nMOS load 21, and the first back gate voltage control element 31 form a first back gate voltage control circuit 301 configured to control the voltage that is applied to the back gate of the first nMOS transistor 10. The first back gate voltage control circuit 301 differs from the back gate voltage control circuit 102 in not having the level shift element 40 and in that the second input terminal of the first back gate voltage control element 31 is connected directly to the drain of the second nMOS transistor 20.

The reference voltage Vcm that is applied to the reference signal input terminal 63 is applied to both the first input terminal of the first back gate voltage control element 31 and the gate of the second nMOS transistor 20. The drain voltage Vd of the second nMOS transistor 20 is applied to the second input terminal of the first back gate voltage control element 31. Further, the first back gate voltage control element 31 applies a voltage to the back gate of the second nMOS transistor 20, which will cause the reference voltage Vcm that is applied to the first input terminal and the drain voltage Vd that is applied to the second input terminal to become equal to each other. Thus, the first back gate voltage control element 31 applies a voltage to the back gate of the second nMOS transistor 20, which will cause the drain voltage Vd when the reference voltage Vcm is applied to the gate via the reference signal input terminal 63 to become equal to the reference voltage Vcm.

Further, the first back gate voltage control element 31 applies a voltage equal to the voltage that is applied to the back gate of the second nMOS transistor 20 to the back gate of the first nMOS transistor 10. Then, the direct-current transfer characteristics of the first nMOS transistor 10 and those of the second nMOS transistor 20 become equal to each other. The threshold voltage of the first nMOS transistor 10 is controlled so as to become a desired value by the first back gate voltage control element 31 using the second nMOS transistor 20 that functions as a replica transistor. In other words, in the amplifier circuit 3, the first back gate voltage control circuit 301 controls the threshold voltage of the first nMOS transistor 10 so as to have the direct-current transfer characteristics such that the drain voltage Vd becomes the reference voltage Vcm when the gate voltage is Vcm.

The second pMOS transistor 22 has a connection relationship corresponding to the second nMOS transistor 20. The second back gate voltage control element 32 has the same configuration and function as those of the back gate voltage control element 30. The second pMOS transistor 22, the second pMOS load 23, and the second back gate voltage control element 32 form a second back gate voltage control circuit 302 configured to control the voltage that is applied to the back gate of the first pMOS transistor 12. In the amplifier circuit 3, the second back gate voltage control circuit 302 controls the threshold voltage of the first pMOS transistor 12 so as to have the direct-current transfer characteristics such that the drain voltage Vd becomes the reference voltage Vcm when the gate voltage is Vcm.

In one example, in the amplifier circuit 3, ½·Vdd is applied as a reference voltage to the reference signal input terminal 63. When ½·Vdd is applied as a reference voltage, the first back gate voltage control circuit 301 controls the threshold voltage of the first nMOS transistor 10 so that the drain voltage Vd becomes ½·Vdd when the gate voltage is ½·Vdd. Further, the second back gate voltage control circuit 302 controls the threshold voltage of the first pMOS transistor 12 so that the drain voltage Vd becomes ½·Vdd when the gate voltage is ½·Vdd.

In the amplifier circuit 3, the first back gate voltage control circuit 301 and the second back gate voltage control circuit 302 respectively control the threshold voltages of the transistors forming the CMOS inverter amplifier unit 300 so that the CMOS inverter amplifier unit 300 has desired direct-current transfer characteristics. In the amplifier circuit 3, it is possible to control the CMOS inverter amplifier unit 300 so as to have desired direct-current transfer characteristics regardless of the fluctuations in the power source voltage, the fluctuations in the operating temperature, and the variation in manufacturing, by controlling the threshold voltages of the transistors forming the CMOS inverter amplifier unit 300.

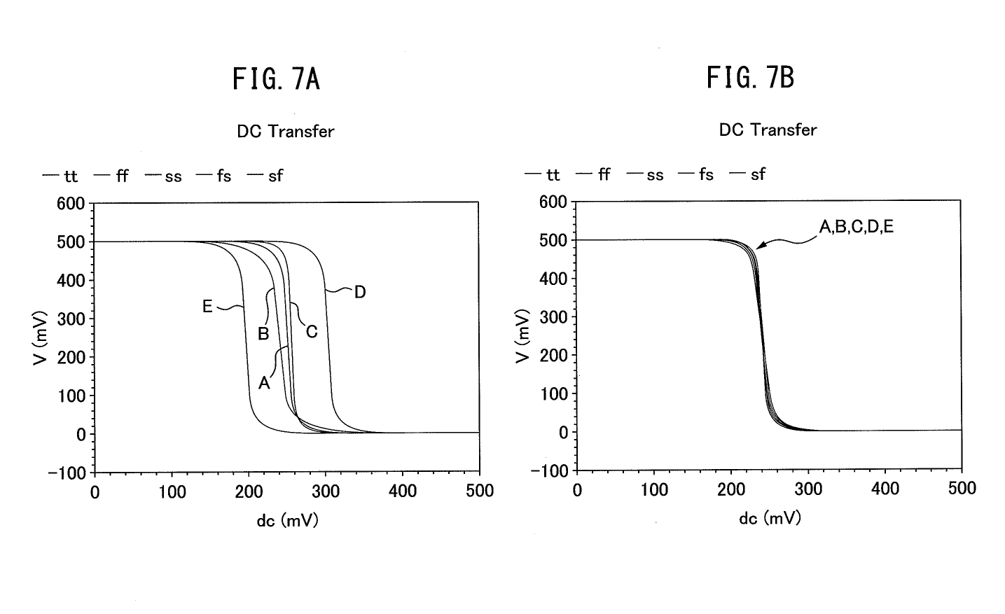

FIG. 7A is a diagram illustrating fluctuations in direct-current transfer characteristics due to the variation in manufacturing of a conventional CMOS inverter amplifier circuit and FIG. 7B is a diagram illustrating fluctuations in direct-current transfer characteristics due to the variation in manufacturing of the amplifier circuit 3. The conventional CMOS inverter amplifier circuit in FIG. 7A has only the configuration corresponding to the CMOS inverter amplifier unit 300 of the amplifier circuit 3 and does not have the configuration corresponding to the first back gate voltage control circuit 301 and the second back gate voltage control circuit 302. In FIGS. 7A and 7B, the horizontal axis represents the input voltage and the vertical axis represents the output voltage. In FIG. 7A and FIG. 7B, arrow A indicates the case where the manufacturing condition of both the nMOS transistor and the pMOS transistor is a typical condition. Arrow B indicates the case where the manufacturing condition of both the nMOS transistor and the pMOS transistor is slow condition and arrow C indicates the case where the manufacturing condition of both the nMOS transistor and the pMOS transistor is fast condition. Arrow D indicates the case where the manufacturing condition of the nMOS transistor is fast condition and the manufacturing condition of the pMOS transistor is slow condition and arrow E indicates the case where the manufacturing condition of the nMOS transistor is slow condition and the manufacturing condition of the pMOS transistor is fast condition. In FIG. 7A and FIG. 7B, the power source voltage Vdd is 0.5 V and in FIG. 7B, the reference voltage Vcm is 0.25 V corresponding to ½·Vdd.

In the conventional CMOS inverter amplifier circuit, the threshold value of the CMOS inverter fluctuates in the range between 0.20 and 0.3 V in accordance with the variation in manufacturing. On the other hand, in the amplifier circuit 3, the threshold value of the CMOS inverter amplifier unit 300 is constant at 0.25 V corresponding to ½·Vdd regardless of the variation in manufacturing.

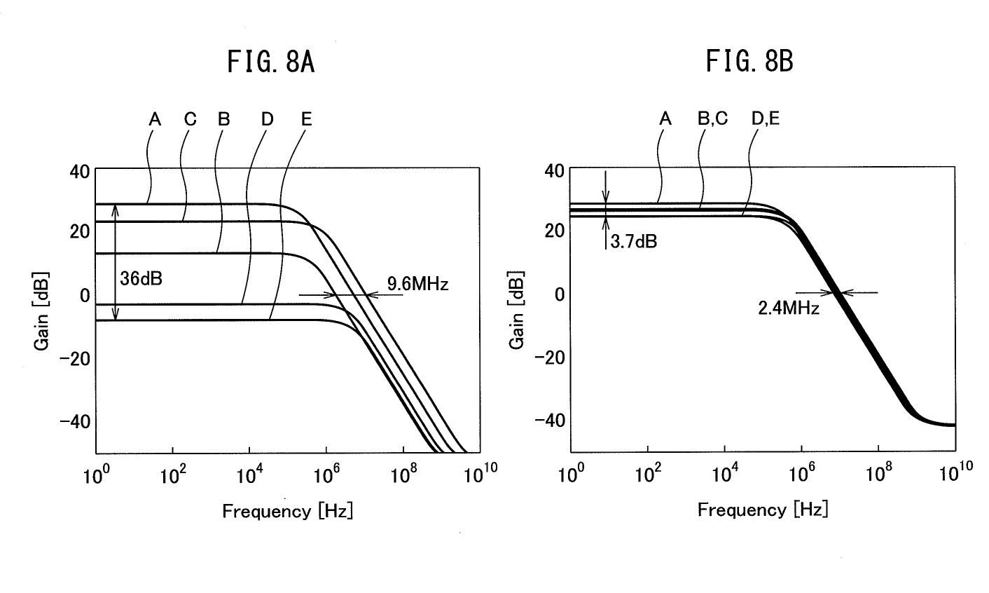

FIG. 8A is a diagram illustrating fluctuations in frequency transfer characteristics of gain due to the variation in manufacturing of the conventional CMOS inverter amplifier circuit and FIG. 8B is a diagram illustrating fluctuations in frequency transfer characteristics of gain due to the variation in manufacturing of the amplifier circuit 3. In FIG. 8A and FIG. 8B, the horizontal axis represents the frequency of the input signal and the vertical axis represents the gain. In FIG. 8A and FIG. 8B, arrows A to E indicate the same manufacturing conditions as in FIG. 7A and FIG. 7B. In FIG. 8A and FIG. 8B, the power source voltage Vdd is 0.5 V and in FIG. 8B, the reference voltage is 0.25 V corresponding to ½·Vdd.

While the gain of the CMOS inverter fluctuates in the range of 36 dB in accordance with the variation in manufacturing in the conventional CMOS inverter amplifier circuit, the range of the fluctuations in gain of the CMOS inverter amplifier unit 300 is 3.7 dB in the amplifier circuit 3. Further, while fluctuations in frequency (cutoff frequency) in the case of unity gain is 9.6 MHz in the conventional CMOS inverter amplifier circuit, fluctuations in frequency in the case of unity gain is 2.4 MHz in the amplifier circuit 3. In the amplifier circuit 3, the fluctuations in both the gain and the unity gain in accordance with the variation in manufacturing are small compared to those of the conventional CMOS inverter amplifier circuit.

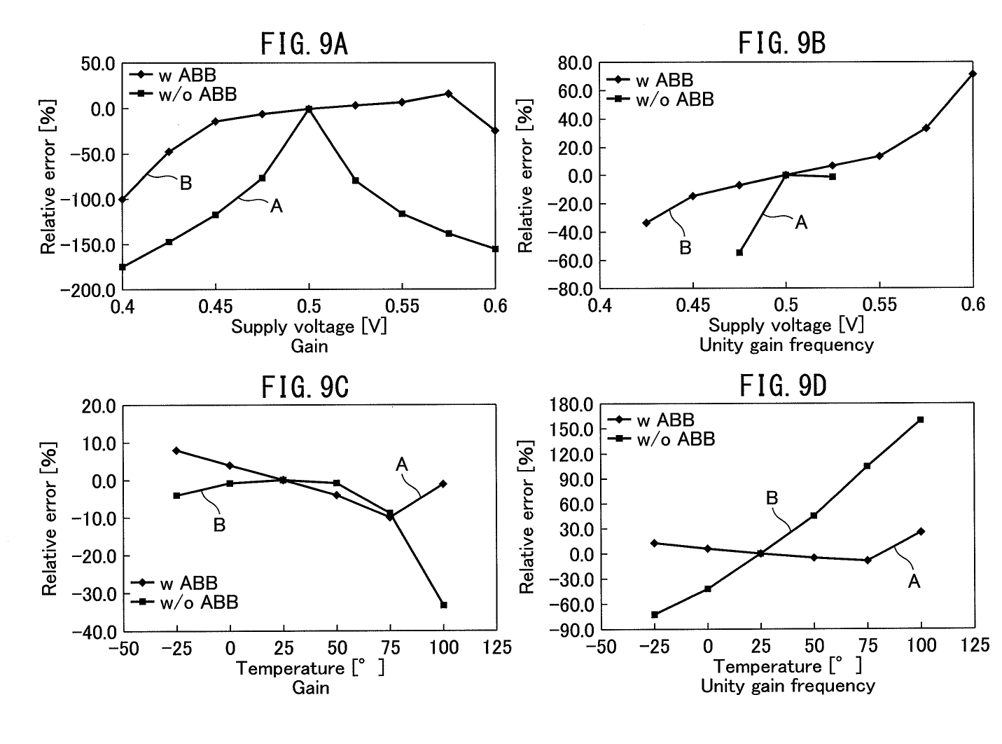

FIG. 9A is a diagram illustrating the fluctuations in the gain due to the fluctuations in the power source voltage of the conventional CMOS inverter amplifier circuit and the amplifier circuit 3 and FIG. 9B is a diagram illustrating the fluctuations in the frequency in the case of the unity gain due to the fluctuations in the power source voltage of the conventional CMOS inverter amplifier circuit and the amplifier circuit 3. FIG. 9C is a diagram illustrating the fluctuations in the gain due to fluctuations in operating temperature of the conventional CMOS inverter amplifier circuit and the amplifier circuit 3. FIG. 9D is a diagram illustrating the fluctuations in the frequency in the case of the unity gain due to the fluctuations in operating temperature of the conventional CMOS inverter amplifier circuit and the amplifier circuit 3. In FIG. 9A and FIG. 9B, the horizontal axis represents the power source voltage and in FIG. 9C and FIG. 9D, the horizontal axis represents the operating temperature. In FIG. 9A, the vertical axis represents the relative error of the gain relative to the gain when the power source voltage is 0.5 V and in FIG. 9B, the vertical axis represents the relative error of the unity gain relative to the unity gain when the power source voltage is 0.5 V. In FIG. 9C, the vertical axis represents the relative error of the gain relative to the gain when the operating temperature is 25° C. and in FIG. 9D, the vertical axis represents the relative error of the unity gain relative to the unity gain when the operating temperature is 25° C. In FIG. 9A to 9D, arrow A indicates the characteristics of a CMOS inverter having the same configuration as that of the conventional CMOS inverter amplifier circuit in FIG. 7A and arrow B indicates the characteristics of the amplifier circuit 3.

The influence of the power source voltage on the frequency in the case of the gain and the unity gain of the amplifier circuit 3 is slight compared to the influence of the power source voltage on the gain and the unity gain of the conventional CMOS inverter amplifier circuit. Further, the influence of the operating temperature on the frequency in the case of the gain and the unity gain of the amplifier circuit 3 is slight compared to the influence of the operating temperature on the frequency in the case of the gain and the unity gain of the conventional CMOS inverter amplifier circuit.

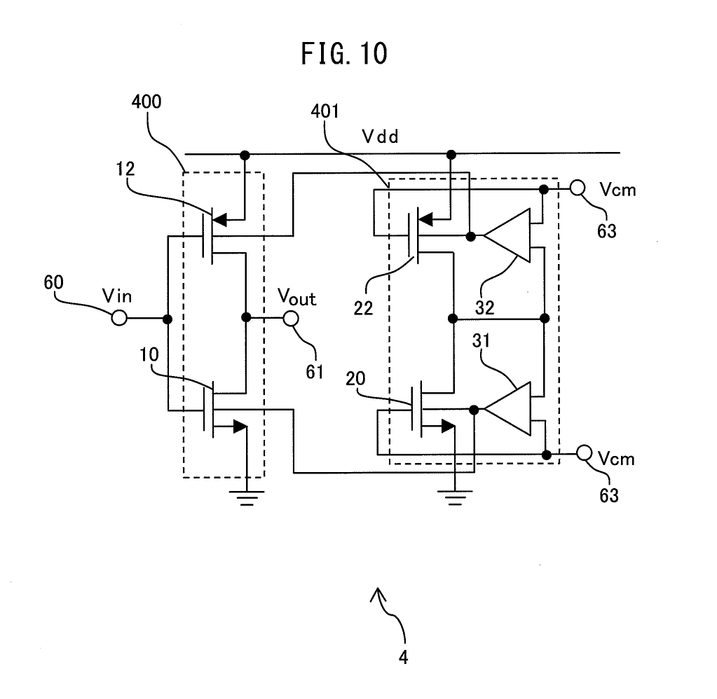

FIG. 10 is a circuit block diagram of an amplifier circuit according to a fourth embodiment.

An amplifier circuit 4 differs from the amplifier circuit 3 in not having the second nMOS load 21 and the second pMOS load 23. In the amplifier circuit 4, the second pMOS transistor 22 functions as the load of the second nMOS transistor 20 and the second nMOS transistor 20 functions as the load of the second pMOS transistor 22, and therefore the second nMOS load 21 and the second pMOS load 23 are omitted.

The first nMOS transistor 10 and the first pMOS transistor 12 form a CMOS inverter amplifier unit 400 configured to amplify a signal that is input to the signal input terminal 60 and to output the amplified signal from the signal output terminal 61. The second nMOS transistor 20, the second pMOS transistor 22, the first back gate voltage control element 31, and the second back gate voltage control element 32 form a back gate voltage control circuit 401. The back gate voltage control circuit 401 controls the voltage that is applied to the back gates of the first nMOS transistor 10 and the first pMOS transistor 12 in accordance with the reference voltage Vcm. The back gate voltage control circuit 401 controls the voltage that is applied to the back gates of the first nMOS transistor 10 and the first pMOS transistor 12 so that the output voltage Vout becomes equal to the reference voltage Vcm when the input voltage Vin is equal to the reference voltage Vcm.

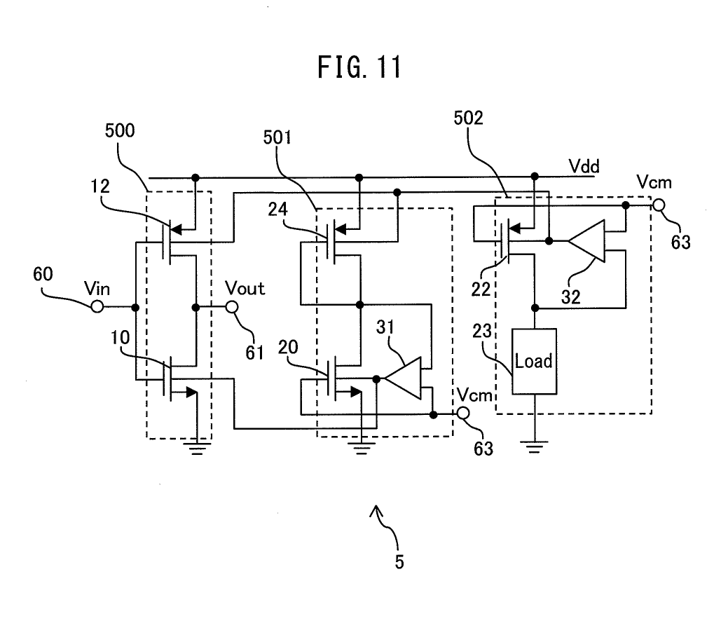

FIG. 11 is a circuit block diagram of an amplifier circuit according to a fifth embodiment.

An amplifier circuit 5 differs from the amplifier circuit 3 in that a third pMOS transistor 24 is arranged in place of the second nMOS load 21. The third pMOS transistor 24 has the same structure as that of the first pMOS transistor 12 and the second pMOS transistor 22 and functions as a replica transistor for controlling the threshold voltage of the first pMOS transistor 12.

The first nMOS transistor 10 and the first pMOS transistor 12 form a CMOS inverter amplifier unit 500 configured to amplify a signal that is input to the signal input terminal 60 and to output the amplified signal from the signal output terminal 61. The second nMOS transistor 20, the third pMOS transistor 24, and the first back gate voltage control element 31 form a first back gate voltage control circuit 501 configured to control the voltage that is applied to the back gate of the first nMOS transistor 10. The second pMOS transistor 22, the second pMOS load 23, and the second back gate voltage control element 32 form a second back gate voltage control circuit 502 configured to control the voltage that is applied to the back gates of the first pMOS transistor 12 and the third pMOS transistor 24.

In the amplifier circuit 5, the MOS transistor of the first back gate voltage control circuit 501 is formed so as to have the same configuration as that of the MOS transistor of the CMOS inverter amplifier unit 500, and therefore the control accuracy of the back gate of the first nMOS transistor 10 further improves.

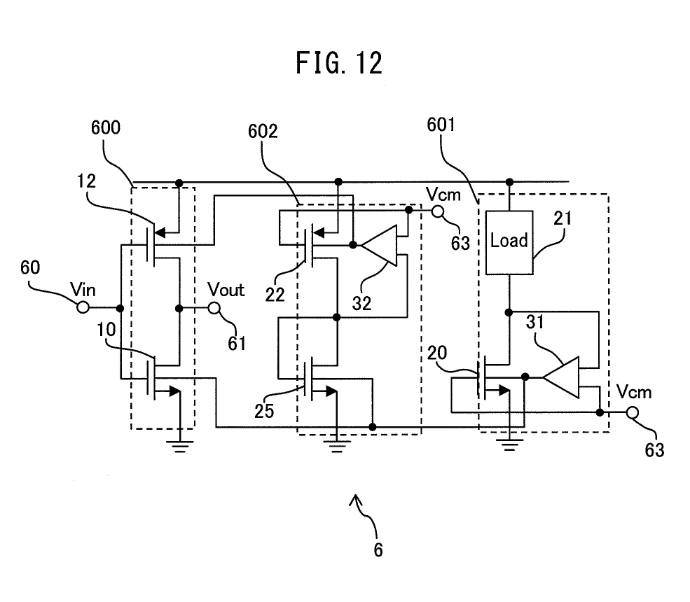

FIG. 12 is a circuit block diagram of an amplifier circuit according to a sixth embodiment.

An amplifier circuit 6 differs from the amplifier circuit 3 in that a third nMOS transistor 25 is arranged in place of the second pMOS load 23. The third nMOS transistor 25 has the same structure as that of the first nMOS transistor 10 and the second nMOS transistor 20 and functions as a replica transistor for controlling the threshold voltage of the first nMOS transistor 10.

A CMOS inverter amplifier unit 600 and a first back gate voltage control circuit 601 have the structure and function corresponding to those of the CMOS inverter amplifier unit 300 and the first back gate voltage control circuit 301. In the amplifier circuit 6, the MOS transistor of a second back gate voltage control circuit 602 is formed so as to have the same configuration as that of the MOS transistor of the CMOS inverter amplifier unit 600, and therefore the control accuracy of the back gate of the first pMOS transistor 12 further improves.

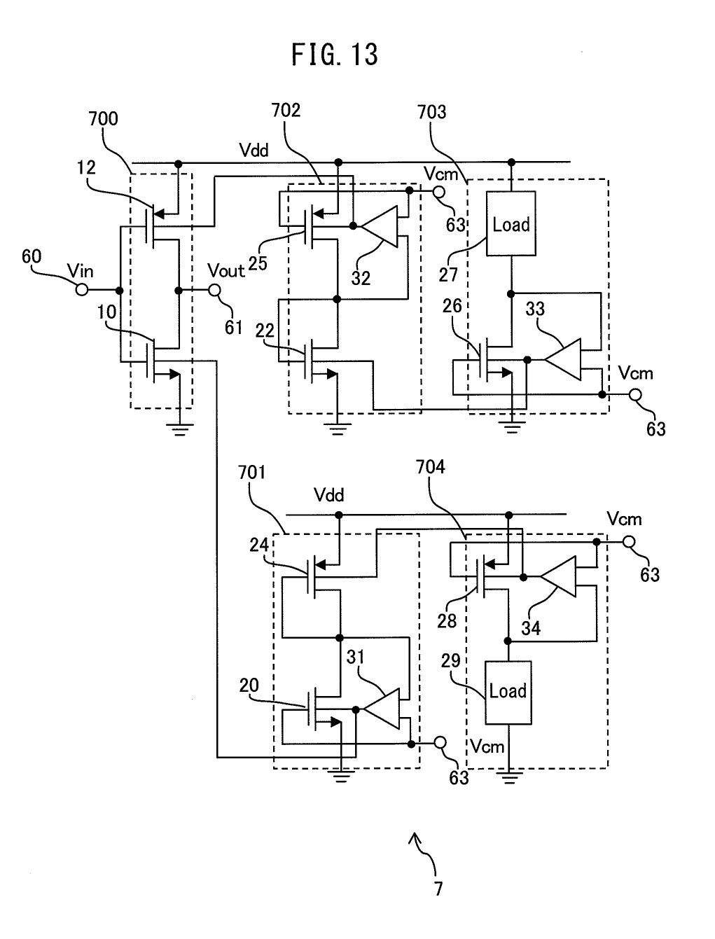

FIG. 13 is a circuit block diagram of an amplifier circuit according to a seventh embodiment.

An amplifier circuit 7 has a first back gate voltage control circuit 701, a second back gate voltage control circuit 702, a third back gate voltage control circuit 703, and a fourth back gate voltage control circuit 704. The first back gate voltage control circuit 701 has the structure and function corresponding to those of the first back gate voltage control circuit 501 of the amplifier circuit 5 and the second back gate voltage control circuit 702 has the structure and function corresponding to those of the second back gate voltage control circuit 602 of the amplifier circuit 6. The third back gate voltage control circuit 703 has the structure corresponding to that of the first back gate voltage control circuit 301 of the amplifier circuit 3 and the fourth back gate voltage control circuit 704 has the structure corresponding to that of the second back gate voltage control circuit 302 of the amplifier circuit 3. A third nMOS transistor 26 has the same structure as that of the second nMOS transistor 20 and a fourth pMOS transistor 28 has the same structure as that of the second pMOS transistor 22. A third nMOS load 27 has the same structure as that of the second nMOS load 21 and a third pMOS load 29 has the same structure as that of the second pMOS load 23. Each of back gate voltage control elements 33 and 34 has the same structure as that of the back gate voltage control element 30 like the back gate voltage control elements 31 and 32.

The third back gate voltage control circuit 703 controls the voltage that is applied to the back gate of the second nMOS transistor 20 by using the third nMOS transistor 26 having the same configuration as that of the second nMOS transistor 20, and the back gate voltage control element 33. The fourth back gate voltage control circuit 704 controls the voltage that is applied to the back gate of the second pMOS transistor 22 by using the fourth pMOS transistor 28 having the same configuration as that of the second pMOS transistor 22, and the back gate voltage control element 34.

In the amplifier circuit 7, the respective MOS transistors of the first back gate voltage control circuit 701 and the second back gate voltage control circuit 702 are formed so as to have the same configuration as that of the MOS transistor of the CMOS inverter amplifier unit 700. In the amplifier circuit 700, the control accuracy of the back gates of both the first nMOS transistor 10 and the first pMOS transistor 12 further improves.

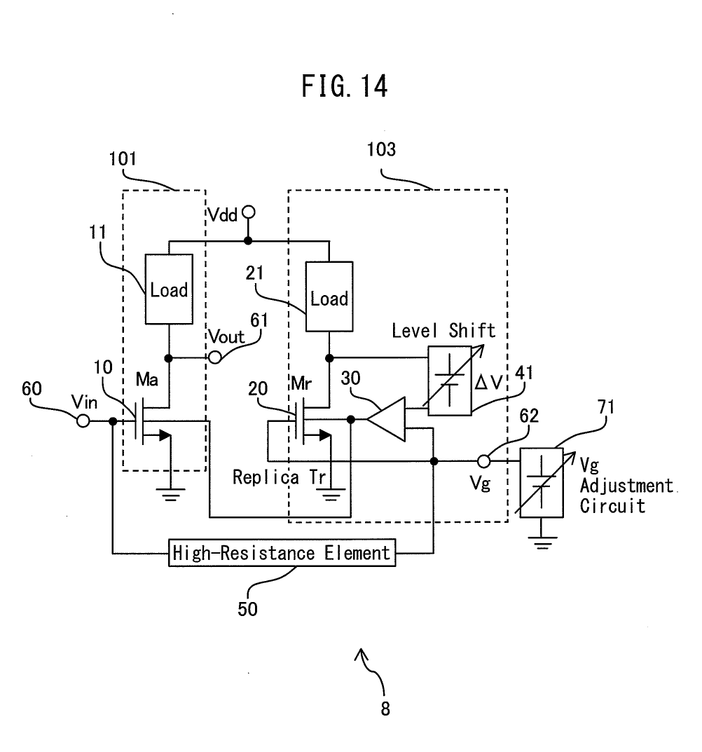

FIG. 14 is a circuit block diagram of an amplifier circuit according to an eighth embodiment.

An amplifier circuit 8 differs from the amplifier circuit 1 in that a back gate voltage control circuit 103 is arranged in place of the back gate voltage control circuit 102 and a gate voltage adjustment circuit 71 is arranged. The back gate voltage control circuit 103 differs from the back gate voltage control circuit 102 in that a level shift element 41 whose step-down voltage ΔV is variable is arranged in place of the level shift element 40. The level shift element 41 is a gate/drain voltage adjustment circuit configured to adjust the voltage between the gate and drain of the first nMOS transistor 10. The gate voltage adjustment circuit 71 is a power source circuit configured to apply the gate voltage Vg of the gate input terminal 62 in such a manner that the gate voltage Vg can be changed and to adjust the gate voltage of the second MOS transistor 20.

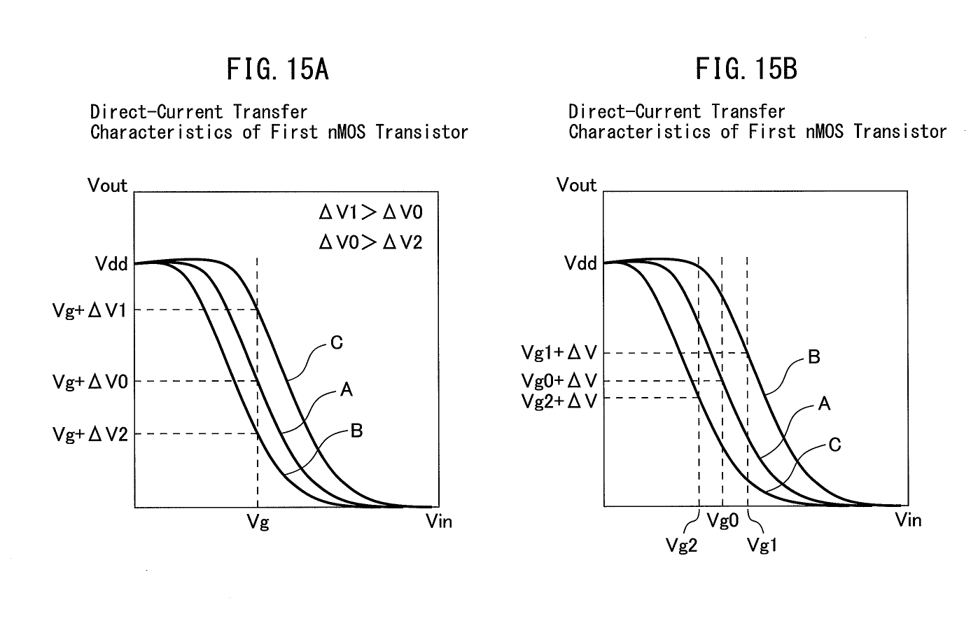

FIG. 15A is a diagram illustrating the direct-current transfer characteristics of the first nMOS transistor 10 when the step-down voltage ΔV of the level shift element 41 is changed in the amplifier circuit 8. FIG. 15B is a diagram illustrating the direct-current transfer characteristics of the first nMOS transistor 10 when the control voltage Vg of the gate voltage adjustment circuit 71 is changed in the amplifier circuit 8.

When the step-down voltage ΔV of the level shift element 41 is changed, the direct-current transfer characteristics of the first nMOS transistor 10 change so that the input voltage Vin and the output voltage Vout satisfy the relationship of (Vout=Vin+ΔV) in accordance with the change in the step-down voltage ΔV. As illustrated in FIG. 15A, when the step-down voltage ΔV is changed from ΔV0 into ΔV1 higher than ΔV0, the change point of the direct-current transfer characteristics of the first nMOS transistor 10 moves toward the high-voltage side. When the step-down voltage ΔV is changed from ΔV0 into ΔV2 lower than ΔV0, the change point of the direct-current transfer characteristics moves toward the low-voltage side.

When the control voltage Vg of the gate voltage adjustment circuit 71 is changed, the direct-current transfer characteristics of the first nMOS transistor 10 change so that the input voltage Vin and the output voltage Vout satisfy the relationship of (Vout=Vin+ΔV). In other words, when the input voltage Vin is Vg0, the output voltage Vout becomes (Vg0+ΔV), when the input voltage Vin is Vg1, the output voltage Vout becomes (Vg1+ΔV), and when the input voltage Vin is Vg2, the output voltage Vout becomes (Vg2+ΔV).

In the amplifier circuit 8, it is possible to control the operating point of the amplifier circuit 8, by controlling the step-down voltage ΔV and the control voltage Vg of the gate voltage adjustment circuit 71. In other words, in the amplifier circuit 8, it is possible to shift the transfer characteristics by adjusting the back gate voltage of the first nMOS transistor 10.

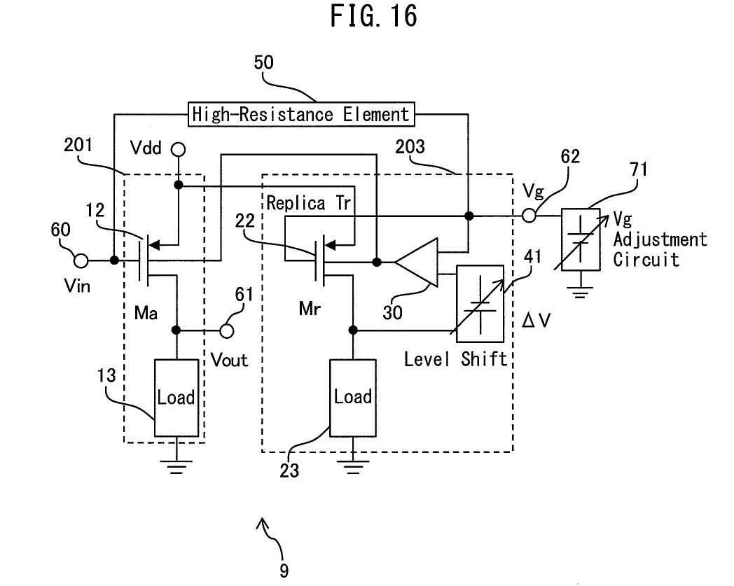

FIG. 16 is a circuit block diagram of an amplifier circuit according to a ninth embodiment.

An amplifier circuit 9 differs from the amplifier circuit 2 in that a back gate voltage control circuit 203 is arranged in place of the back gate voltage control circuit 202, and the gate voltage adjustment circuit 71 is arranged. The back gate voltage control circuit 203 differs from the back gate voltage control circuit 202 in that the level shift element 41 is arranged. In the amplifier circuit 9, it is possible to control the operating point of the amplifier circuit 9, by controlling the step-down voltage ΔV and the control voltage Vg of the gate voltage adjustment circuit 71.

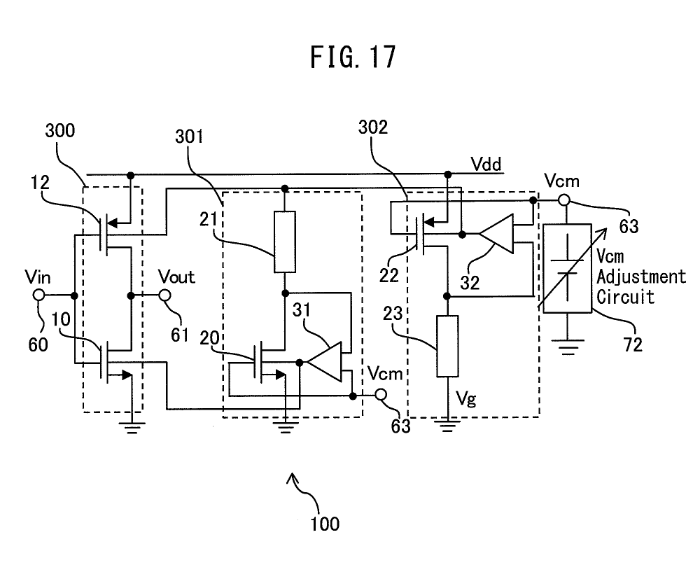

FIG. 17 is a circuit block diagram of an amplifier circuit according to a tenth embodiment.

An amplifier circuit 100 differs from the amplifier circuit 3 in that a reference voltage control circuit 72 is arranged. The reference voltage control circuit 72 is a power source circuit configured to apply the reference voltage Vcm to the reference signal input terminal 63 in such a manner that the reference voltage Vcm can be changed. In the amplifier circuit 100, it is possible to control the operating point of the amplifier circuit 100 by controlling the reference voltage Vcm.

In the amplifier circuits according to the embodiments, by controlling the back gate voltage of the MOS transistor forming the amplifier unit by using the back gate voltage control circuit, it is possible to change the direct-current transfer characteristics of the amplifier unit to desired characteristics.

In the amplifier circuits according to the embodiments, the back gate voltage control element is formed by an operational amplifier whose number of stages of the MOS transistors connected in series between the power source voltage Vdd and the ground is two or less, and therefore the operation at a low voltage is enabled.

In the amplifier circuits 8 and 9, it is possible to shift the direct-current transfer characteristics, by changing the step-down voltage ΔV that is stepped down by the level shift element 41 and the voltage Vg that is input to the gate input terminal 62, and therefore it is possible to cause the amplifier circuits 8 and 9 to operate as a small-signal variable gain amplifier circuit. Further, in the amplifier circuit 100, by changing the reference voltage Vcm that is input to the reference signal input terminal 63, it is possible to shift the direct-current transfer characteristics, and therefore it is possible to cause the amplifier circuit 100 to operate as a small-signal variable gain amplifier circuit.

In the amplifier circuits according to the embodiments, the MOS transistor forming the amplifier unit and the replica transistor have the same structure, but it may also be possible for the MOS transistor forming the amplifier unit and the replica transistor to have different structures with different gate lengths.

The amplifier circuits according to the embodiments explained with reference to FIG. 2 to FIG. 17 function as a comparator circuit when a digital signal is input to the signal input terminal 60. When a signal having a value greater than the threshold value of the first nMOS transistor 10 is input, the amplifier circuit 1 outputs a signal indicating “0”. The threshold value is specified in accordance with the gate voltage that is input to the gate input terminal 62. When a signal having a value smaller than the threshold value of the first nMOS transistor 10 is input, the amplifier circuit 1 outputs a signal indicating “1”. Further, each of the amplifier circuits 8, 9, and 100 functions as a comparator circuit whose threshold value is variable.

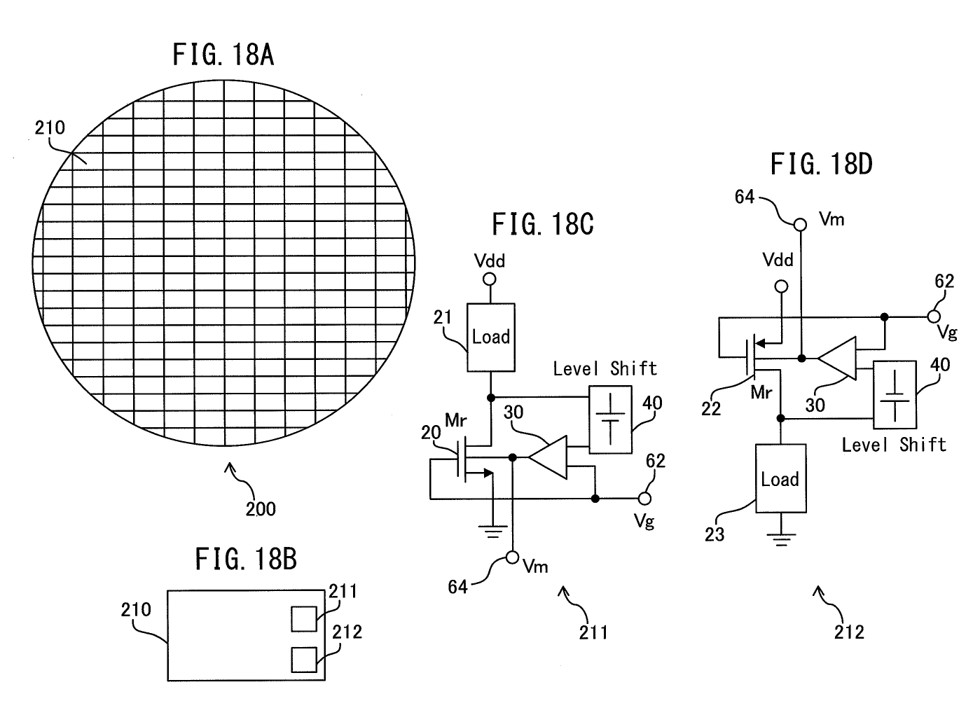

FIG. 18A is a plan view of a semiconductor wafer according to an embodiment and FIG. 18B is a plan view of a semiconductor device that is formed on the semiconductor wafer illustrated in FIG. 18A. FIG. 18C and FIG. 18D are each a circuit diagram of a variation detection circuit that is mounted on the semiconductor device illustrated in FIG. 18B.

On a semiconductor wafer 200, a plurality of semiconductor devices 210 is formed. Each of the plurality of semiconductor devices 210 has an nMOS transistor variation detection circuit 211 and a pMOS transistor variation detection unit 212. The nMOS transistor variation detection circuit 211 has the same configuration as that of the back gate voltage control circuit 102 of the amplifier circuit 1 and the pMOS transistor variation detection unit 212 has the same configuration as that of the back gate voltage control circuit 202 of the amplifier circuit 2. Each of the nMOS transistor variation detection circuit 211 and the pMOS transistor variation detection unit 212 outputs a monitor voltage Vm from a monitor terminal 64 when a predetermined voltage is applied to the gate input terminal 62.

The monitor voltage Vm that is output from the monitor terminal 64 changes in accordance with the manufacturing condition of the nMOS transistor and the pMOS transistor forming the semiconductor device 210, and therefore it is possible to estimate the manufacturing condition of the semiconductor device 210, by detecting the monitor voltage Vm. Further, it is possible to estimate the variation in manufacturing within the semiconductor wafer 200, by detecting the monitor voltages Vm of the nMOS transistor variation detection circuit 211 and the pMOS transistor variation detection unit 212 of the semiconductor device 210 formed on the semiconductor wafer 200. On the semiconductor wafer 200, the nMOS transistor variation detection circuit 211 and the pMOS transistor variation detection unit 212 are arranged inside the semiconductor device 210, but they may be formed in a scribe area that partitions the semiconductor devices 210 individually.

It is possible to estimate the manufacturing condition of the semiconductor device 210, by mounting the nMOS transistor variation detection circuit 211 and the pMOS transistor variation detection unit 212 on the semiconductor device 210. Further, it is possible to estimate the variation in manufacturing of the semiconductor device 210 that is formed on the semiconductor wafer 200, by detecting the monitor voltage Vm.

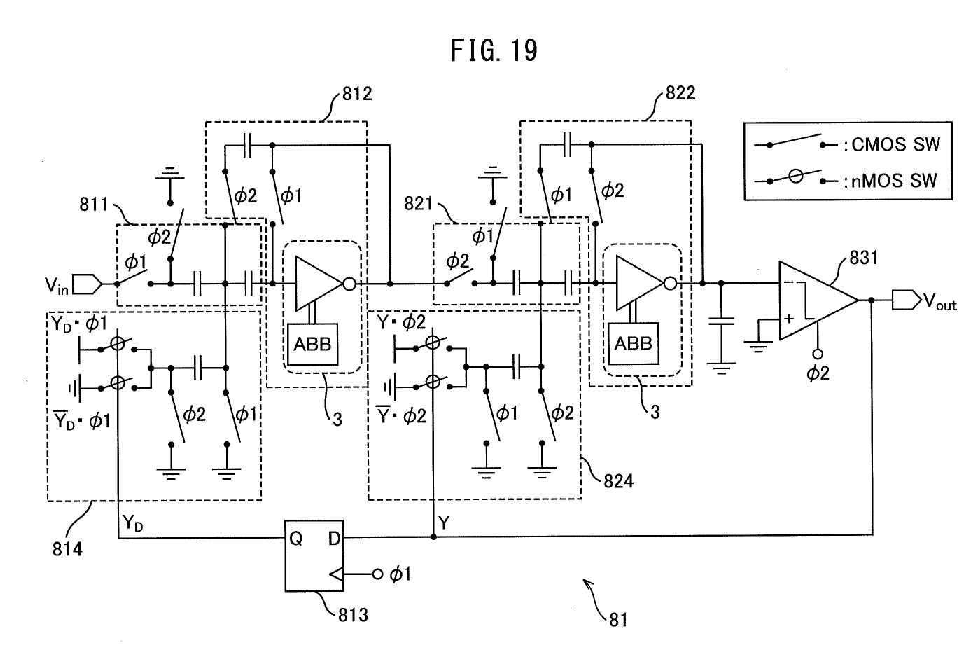

FIG. 19 is a circuit block diagram of a ΔΣ analog-to-digital converter circuit according to an embodiment.

A ΔΣAD converter circuit 81 is a secondary ΔΣAD converter circuit. The ΔΣAD converter circuit 81 has a primary addition circuit 811, a primary integral circuit 812, a flip-flop circuit 813, and a primary digital-to-analog converter circuit 814. Further, the ΔΣAD converter circuit 81 has a secondary addition circuit 821, a secondary integral circuit 822, a secondary digital-to-analog converter circuit 824, and a comparator circuit 831. The flip-flop circuit 813 and the primary digital-to-analog converter circuit 814 are each a feedback circuit configured to delay the output signal of the comparator circuit 831 that functions as a quantizer, to carry out digital-to-analog converter, and to output the signal to the primary addition circuit 811 as a feedback signal.

The primary addition circuit 811 adds the analog signal Vin that is input and the output signal of the primary digital-to-analog converter circuit 814 and outputs the sum to the primary integral circuit 812. The secondary addition circuit 821 adds the output signal of the primary integral circuit 812 and the output signal of the secondary digital-to-analog converter circuit 824 and outputs the sum to the secondary integral circuit 822.

Each of the primary integral circuit 812 and the secondary integral circuit 822 is an integral circuit having the amplifier circuit 3 as an amplifier circuit. As described above, the amplifier circuit 3 has the CMOS inverter amplifier unit 300 (in FIG. 19, illustrated as an inverter element), the first back gate voltage control circuit 301, and the second back gate voltage control circuit 302 (in FIG. 19, illustrated as ABB). The primary integral circuit 812 integrates the output signal of the primary addition circuit 811 and outputs the integral to the secondary addition circuit 821. The secondary integral circuit 822 integrates the output signal of the secondary addition circuit 821 and outputs the integral to the comparator circuit 831.

The comparator circuit 831 outputs a quantized signal of “0” or “1” in accordance with the magnitude of the analog signal Vin and the output signal of the primary digital-to-analog converter circuit 814. When the analog signal Vin is greater in magnitude than the output signal of the primary digital-to-analog converter circuit 814, the comparator circuit 831 outputs “1”. When the analog signal Vin is smaller in magnitude than the output signal of the primary digital-to-analog converter circuit 814, the comparator circuit 831 outputs “0”.

The flip-flop circuit 813 functions as a delay circuit configured to delay the output signal of the comparator circuit 831 by one cycle.

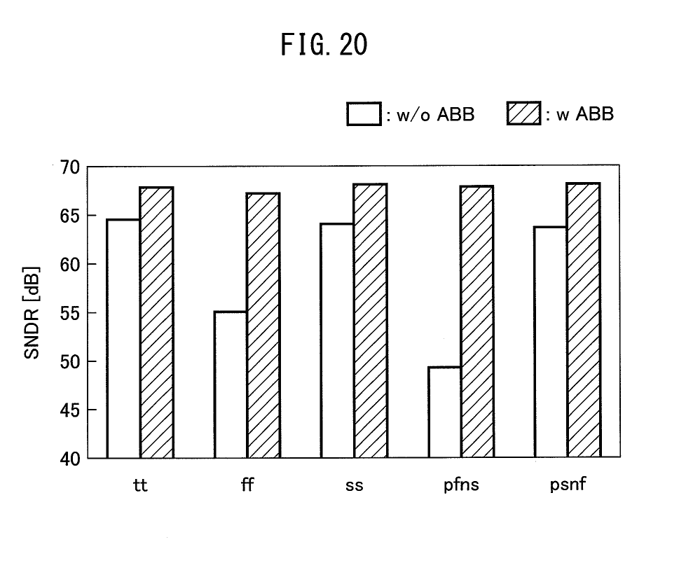

FIG. 20 is a diagram illustrating fluctuations in SNDR (Signal-to-noise and distortion ratio) of the conventional ΔΣAD converter circuit and the ΔΣAD converter circuit 81 due to the variation in manufacturing. In FIG. 20, the horizontal axis represents the manufacturing condition and the vertical axis represents the SNDR. In FIG. 20, tt indicates the case where the manufacturing condition of both the nMOS transistor and the pMOS transistor is typical condition, ff indicates the case where the manufacturing condition of both the nMOS transistor and the pMOS transistor is fast condition, ss indicates the case where the manufacturing condition of both the nMOS transistor and the pMOS transistor is slow condition, pfns indicates the case where the manufacturing condition of the nMOS transistor is slow condition and the manufacturing condition of the pMOS transistor is fast condition, and psnf indicates the case where the manufacturing condition of the nMOS transistor is fast condition and the manufacturing condition of the pMOS transistor is slow condition. While the conventional ΔΣAD converter circuit is a CDS (Correlated Double Sampling) integral circuit, the ΔΣAD converter circuit 81 is a CLS (Correlated Level Shift) integral circuit.

The fluctuations in the manufacturing condition of the ΔΣAD converter circuit 81 are very small compared to the fluctuations in the manufacturing condition of the conventional ΔΣAD converter circuit.

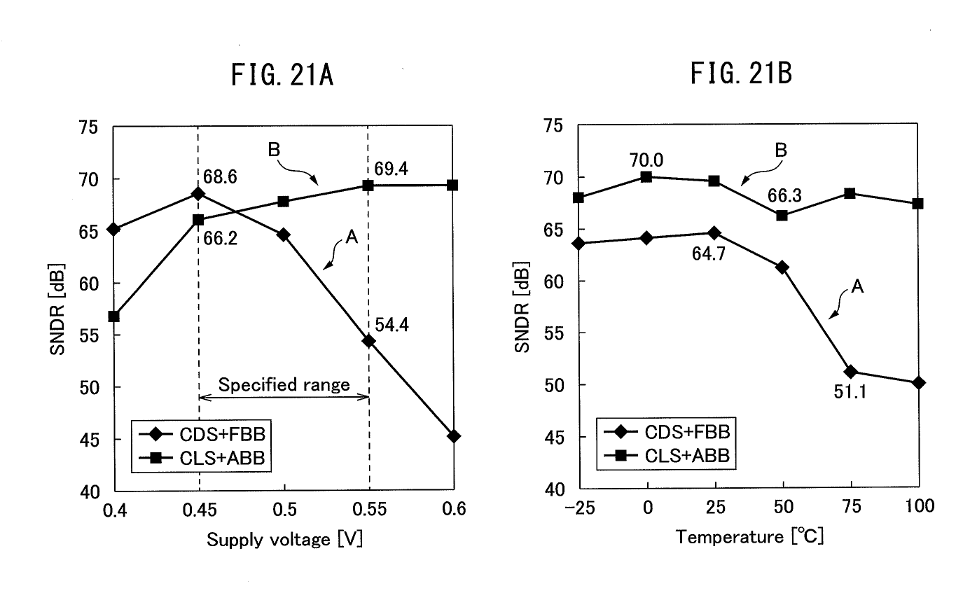

FIG. 21A is a diagram illustrating the fluctuations in the SNDR due to the fluctuations in the power source voltage of the conventional ΔΣAD converter circuit and the ΔΣAD converter circuit 81 and FIG. 21B is a diagram illustrating the fluctuations in the SNDR due to the fluctuations in the operating temperature of the conventional ΔΣAD converter circuit and the ΔΣAD converter circuit 81. In FIG. 21A, the horizontal axis represents the power source voltage, in FIG. 21B, the horizontal axis represents the operating temperature, and in FIG. 21A and FIG. 21B, the vertical axis represents the SNDR. In FIG. 21A and FIG. 21B, arrow A indicates the characteristics of the conventional ΔΣAD converter circuit and arrow B indicates the characteristics of the ΔΣAD converter circuit 81. In FIG. 21A, in the conventional ΔΣAD converter circuit, a fixed forward bias voltage is applied to the back gate by FBB (Forward Body Bias).

In the conventional ΔΣAD converter circuit, in order to enable a low-voltage operation, a fixed forward bias voltage is applied to the back gate by the FBB. On the other hand, in the ΔΣAD converter circuit 81, it is possible to set an arbitrary voltage to the back gate by feedback.

The fluctuations in the SNDR due to the power source voltage and the operating temperature of the ΔΣAD converter circuit 81 are very small compared to the fluctuations due to the power source voltage and the operating temperature of the conventional ΔΣAD converter circuit. While the deviation of the SNDR due to the fluctuations in the power source voltage of 0.5 V±10% is 14.2 dB in the conventional ΔΣAD converter circuit, the deviation of the SNDR is 3.2 dB in the ΔΣAD converter circuit 81. Further, while the deviation of the SNDR due to the fluctuations in the operating temperature of −25° C. to 100° C. is 14.7 dB in the conventional ΔΣAD converter circuit, the deviation of the SNDR is 3.7 dB in the ΔΣAD converter circuit 81.

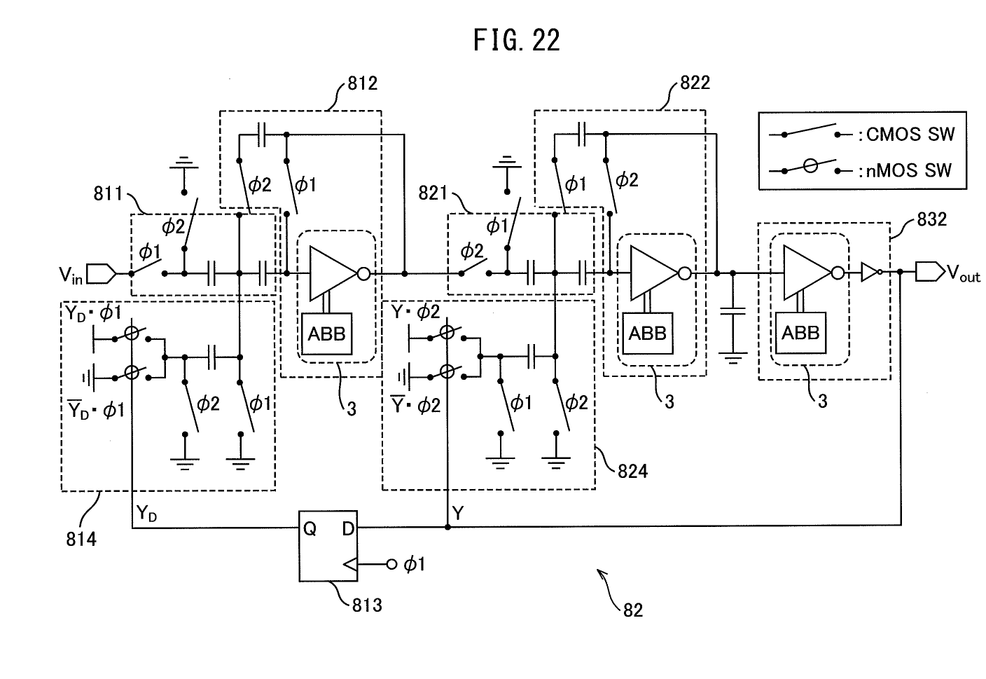

FIG. 22 is a circuit block diagram of a ΔΣ analog-to-digital converter circuit according to another embodiment.

A ΔΣAD converter circuit 82 differs from the ΔΣAD converter circuit 81 in that a comparator circuit 832 having an inversion comparator circuit 3 having the same configuration as that of the amplifier circuit 3 is arranged in place of the comparator circuit 831. Since the ΔΣAD converter circuit 82 has the inversion comparator circuit 3 having the same configuration as that of the amplifier circuit 3, it is possible to keep the threshold value of the comparator circuit 832 at a fixed value regardless of the fluctuations in the power source voltage, the operating temperature, and the manufacturing condition.

It is also possible for a plurality of amplifier circuits 3 to share one ABB circuit.

What is claimed is:

1. An amplifier circuit comprising:
a first MOS transistor whose source is connected to a first power source which amplifies a signal that is input to a gate and outputs the amplified signal from a drain;
a second MOS transistor whose source is connected to the first power source; and
a back gate voltage control element that controls the voltage a back gate of the second MOS transistor so that the voltage associated with the drain of the second MOS transistor and the voltage of the gate of the second MOS transistor are equal to each other, and which applies the controlled voltage to the back gate of the first MOS transistor.

2. The amplifier circuit according to claim 1, wherein
the back gate voltage control element is an operational amplifier.

3. The amplifier circuit according to claim 2, wherein
in the operational amplifier, the number of stages of MOS transistors that are connected in series between the first power source and a second power source whose voltage is different from that of the first power source is two or less.

4. The amplifier circuit according to claim 1, further comprising a gate voltage adjustment circuit configured to adjust the gate voltage of the second MOS transistor.

5. The amplifier circuit according to claim 1, further comprising a gate-drain voltage adjustment circuit configured to adjust the voltage between the gate and the drain of the second MOS transistor.

6. A CMOS inverter amplifier circuit comprising:
a CMOS inverter having:
a first nMOS transistor whose gate is connected to an input terminal, whose source is connected to a first power source, and whose drain is connected to an output terminal; and
a first pMOS transistor whose gate is connected to the input terminal, whose source is connected to a second power source whose voltage is different from the voltage of the first power source, and whose drain is connected to the output terminal, and
amplifying a signal that is input to the input terminal and outputting the amplified signal from the output terminal;
a second nMOS transistor whose source is connected to the first power source;
a second pMOS transistor whose source is connected to the second power source;
an nMOS back gate voltage control element that controls the voltage of the back gate of the second nMOS transistor so that the voltage associated with the drain of the second nMOS transistor and the voltage of the gate of the second nMOS transistor are equal to each other, and which applies the controlled voltage to the back gate of the first nMOS transistor; and
a pMOS back gate voltage control element that controls the voltage of the back gate of the second pMOS transistor so that the voltage associated with the drain of the second pMOS transistor and the voltage of the gate of the second pMOS transistor are equal to each other, and which applies the controlled voltage to the back gate of the first pMOS transistor.

7. A comparator circuit comprising:
a first MOS transistor whose source is connected to a first power source and which amplifies a signal that is input to a gate and outputs the amplified signal from a drain;
a second MOS transistor whose source is connected to the first power source; and
a back gate voltage control element that controls the voltage a back gate of the second MOS transistor so that the voltage associated with the drain of the second MOS transistor and the voltage of the gate of the second MOS transistor are equal to each other, and which applies the controlled voltage to the back gate of the first MOS transistor.

8. A comparator circuit comprising:
a CMOS inverter having:
a first nMOS transistor whose gate is connected to an input terminal, whose source is connected to a first power source, and whose drain is connected to an output terminal; and
a first pMOS transistor whose gate is connected to the input terminal, whose source is connected to a second power source whose voltage is different from the voltage of the first power source, and whose drain is connected to the output terminal, and
amplifying a signal that is input to the input terminal and outputting the amplified signal from the output terminal;
a second nMOS transistor whose source is connected to the first power source;
a second pMOS transistor whose source is connected to the second power source;
an nMOS back gate voltage control element that controls the voltage of the back gate of the second nMOS transistor so that the voltage associated with the drain of the second nMOS transistor and the voltage of the gate of the second nMOS transistor are equal to each other, and which applies the controlled voltage to the back gate of the first nMOS transistor; and
a pMOS back gate voltage control element that controls the voltage of the back gate of the second pMOS transistor so that the voltage associated with the drain of the second pMOS transistor and the voltage of the gate of the second pMOS transistor are equal to each other, and which applies the controlled voltage to the back gate of the first pMOS transistor.

9. A ΔΣ analog-to-digital converter comprising:
an adder configured to add an analog signal and a feedback signal;
an integral circuit including the CMOS inverter amplifier circuit;
a quantizer configured to quantize an output signal of the integral circuit; and
a feedback circuit configured to delay an output signal of the quantizer, to carry out digital-to-analog converter, and to output the feedback signal, wherein CMOS inverter amplifier circuit including:
a CMOS inverter having:
a first nMOS transistor whose gate is connected to an input terminal, whose source is connected to a first power source, and whose drain is connected to an output terminal; and
a first pMOS transistor whose gate is connected to the input terminal, whose source is connected to a second power source whose voltage is different from the voltage of the first power source, and whose drain is connected to the output terminal, and
amplifying a signal that is input to the input terminal and outputting the amplified signal from the output terminal;
a second nMOS transistor whose source is connected to the first power source;
a second pMOS transistor whose source is connected to the second power source;
an nMOS back gate voltage control element that controls the voltage of the back gate of the second nMOS transistor so that the voltage associated with the drain of the second nMOS transistor and the voltage of the gate of the second nMOS transistor are equal to each other, and which applies the controlled voltage to the back gate of the first nMOS transistor; and
a pMOS back gate voltage control element that controls the voltage of the back gate of the second pMOS transistor so that the voltage associated with the drain of the second pMOS transistor and the voltage of the gate of the second pMOS transistor are equal to each other, and which applies the controlled voltage to the back gate of the first pMOS transistor.

10. The ΔΣ analog-to-digital converter according to claim 9, wherein the quantizer includes the comparator circuit including:
a CMOS inverter having:
a first nMOS transistor whose gate is connected to an input terminal, whose source is connected to a first power source, and whose drain is connected to an output terminal; and
a first pMOS transistor whose gate is connected to the input terminal, whose source is connected to a second power source whose voltage is different from the voltage of the first power source, and whose drain is connected to the output terminal, and
amplifying a signal that is input to the input terminal and outputting the amplified signal from the output terminal;
a second nMOS transistor whose source is connected to the first power source;
a second pMOS transistor whose source is connected to the second power source;
an nMOS back gate voltage control element that controls the voltage of the back gate of the second nMOS transistor so that the voltage associated with the drain of the second nMOS transistor and the voltage of the gate of the second nMOS transistor are equal to each other, and which applies the controlled voltage to the back gate of the first nMOS transistor; and
a pMOS back gate voltage control element that controls the voltage of the back gate of the second pMOS transistor so that the voltage associated with the drain of the second pMOS transistor and the voltage of the gate of the second pMOS transistor are equal to each other, and which applies the controlled voltage to the back gate of the first pMOS transistor.

11. A semiconductor device comprising:
a MOS transistor whose source is connected to a first power source; and
a variation detection circuit having a back gate voltage detection element that controls the voltage of a back gate of the MOS transistor so that the voltage associated with the MOS transistor and the voltage of the gate of the MOS transistor are equal to each other, and which outputs an output signal indicating the controlled voltage.
